(19) United States
(12) Patent Application Publication
(10) Pub. No.: US 2013/0108063 A1
(43) Pub. Date: May 2, 2013

(54) INVOKING AND SUPPORTING DEVICE TESTING THROUGH AUDIO CONNECTORS

(71) Applicants: Dustin J. Verhoeve, San Francisco, CA (US); Saket R. Vora, San Francisco, CA (US); Joseph R. Fisher, JR., San Jose, CA (US); Erturk D. Kocalar, Sunnyvale, CA (US); Casey Hardy, San Francisco, CA (US); Brian J. Conner, San Jose, CA (US); Adriane S. Niehaus, San Jose, CA (US)

(72) Inventors: Dustin J. Verhoeve, San Francisco, CA (US); Saket R. Vora, San Francisco, CA (US); Joseph R. Fisher, JR., San Jose, CA (US); Erturk D. Kocalar, Sunnyvale, CA (US); Casey Hardy, San Francisco, CA (US); Brian J. Conner, San Jose, CA (US); Adriane S. Niehaus, San Jose, CA (US)

(21) Appl. No.: 13/286,439

(22) Filed: Nov. 1, 2011

(51) Int. Cl. H04R 29/00; G01R 31/3187

(52) U.S. Cl. 381/58; 324/750.3; 714/727; 714/E11.001

(57) ABSTRACT

Electronic devices may be provided with audio circuits and circuitry configured to support communications and test mode operations. During normal operation, a connector such as an audio connector may be inserted into a connector port in an electronic device. The audio connector may be associated with a headset or other accessory and may be used to carry audio signals. During test mode operations, a tester may be coupled to the connector port using an audio connector. The tester may generate voltages, resistances, time-varying signals, or other input that directs the device to configure switching circuitry to support testing. Monitoring circuitry in the device may be used to detect input from the tester. In response to detected input from the tester, the switching circuitry may be adjusted to couple a control circuit that supports test mode operations to the audio connector.

### BACKGROUND

This relates generally to electronic devices, and, more particularly, to testing electronic devices.

Electronic devices such as media players, portable computers, and cellular telephones are generally tested during manufacturing. Testing is often performed using procedures that are compliant with the IEEE 1149.1 standard. This type of testing, which is sometimes referred to as Joint Test Action Group (JTAG) testing, can be used to capture and analyze scan chain data and perform other debug procedures.

Challenges can arise with conventional JTAG testing procedures. In some situations, it is necessary to probe a printed circuit board within a device to perform tests or to make manufacturing changes to a printed circuit board once testing is complete. Other test procedures rely on device software that is susceptible to freezing.

It would therefore be desirable to be able to provide improved techniques for testing electronic devices.

### SUMMARY

Electronic devices may be provided with audio circuits and circuitry such as controller circuitry that is configured to support communications and test mode operations. An electronic device may have a port with which external equipment may be coupled to the electronic device.

During normal operation, a connector such as an audio connector may be inserted into a connector port in an electronic device. The audio connector may be associated with a headset or other accessory and may be used to carry audio signals. For example, the audio connector may have a microphone terminal for carrying microphone signals and left and right audio terminals for carrying stereo audio.

During test mode operations, a connector associated with a tester may be inserted into the connector port. For example, an audio plug associated with the tester may be inserted into an audio jack in an electronic device. Using a monitor circuit, the electronic device can monitor contacts in the audio jack for commands from the tester.

To place the electronic device in test mode, the tester may supply the electronic device with input through the audio jack in the electronic device. The tester may, for example, apply a predetermined voltage to a microphone contact or other contact in the audio jack, may apply a pattern of voltages to contacts in the audio jack, may produce resistance values across one or more pairs of terminals within the audio jack, may generate time-varying signals that are applied to one or more contacts within the audio jack, or may produce other signals that direct the electronic device to enter test mode.

The electronic device may have a monitor circuit that monitors signals on the audio jack or other connector. In response to detecting predetermined signals on the audio jack or other connector with the monitor circuit, the electronic device may enter test mode and may use the controller circuitry to support test mode operations. During testing, the tester that issued signals to the electronic device to place the device in test mode may be used in transmitting and receiving test data with the controller circuitry in the electronic device. Arrangements of this type may facilitate testing (e.g., JTAG testing) of enclosed electronic devices. Enclosed electronic devices may include, as examples, devices that do not include dedicated JTAG external connectors and devices in which accessing internal circuit boards for JTAG testing may require disassembly of the devices.

Further features of the invention, its nature and various advantages will be more apparent from the accompanying drawings and the following detailed description of the preferred embodiments.

### BRIEF DESCRIPTION OF THE DRAWINGS

FIG. 1 is a diagram of an illustrative system in which an electronic device and external equipment may be operated in accordance with an embodiment of the present invention.

FIG. 2 is a circuit diagram of illustrative circuitry of the type that may be used in the electronic device of FIG. 1 in accordance with an embodiment of the present invention.

FIG. 3 is a state diagram showing operations involved in monitoring whether a tester has directed an electronic device to enter test mode in accordance with an embodiment of the present invention.

FIG. 4 is a circuit diagram showing illustrative circuitry that may be used in an electronic device that contains an audio connector, an audio circuit, and a circuit configured to support test mode operations in accordance with an embodiment of the present invention.

FIG. 5 is a diagram of an illustrative female audio connector of the type that may be used in an electronic device and an illustrative male audio connector of the type that may be coupled to the female audio connector in accordance with an embodiment of the present invention.

FIG. 6 is a cross-sectional side view of an illustrative audio connector inserted into a mating female audio connector in an electronic device in accordance with an embodiment of the present invention.

FIG. 7 is a diagram of an illustrative tester that may be used in testing a device in accordance with an embodiment of the present invention.

FIG. 8 is a diagram of illustrative circuitry that may be used in a device that is being tested using a tester of the type shown in FIG. 7 in accordance with an embodiment of the present invention.

FIG. 9 is a table of illustrative voltages that may be used in connection with operating a device in accordance with an embodiment of the present invention.

FIG. 10 is a table showing how patterns of voltages may be provided to different contacts in a connector in a device in accordance with an embodiment of the present invention.

FIGS. 11 and 12 are graphs showing illustrative time-varying voltages that may be supplied to a connector in a device in accordance with an embodiment of the present invention.

FIG. 13 is a table showing patterns of resistances that may be imposed across different pairs of contacts in a device connector in accordance with an embodiment of the present invention.

FIG. 14 is a flow chart of steps involved in controlling a device during testing in accordance with an embodiment of the present invention.

FIG. 15 is a system diagram showing equipment of the type that may be used in implementing a secure testing protocol in accordance with an embodiment of the present invention.

FIG. 16 is a flow chart of illustrative steps involved in implementing a secure testing protocol in accordance with an embodiment of the present invention.

### DETAILED DESCRIPTION

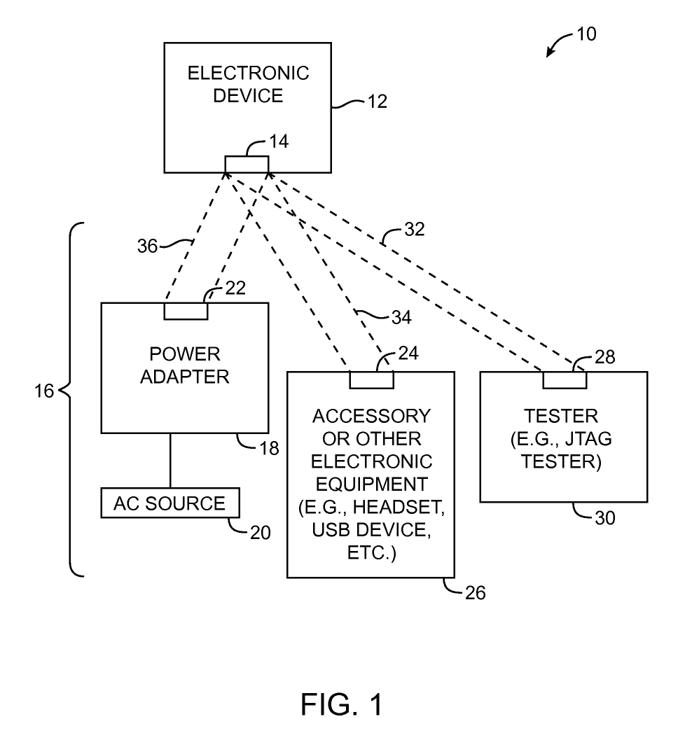

Electronic devices may be provided with circuitry that supports testing. An illustrative system environment for a device that has circuitry that supports testing is shown in FIG. 1. As shown in FIG. 1, system 10 may include an electronic device such as electronic device 12. Electronic device 12 may be a portable electronic device or other suitable electronic device. For example, electronic device 12 may be a laptop computer, a tablet computer, a somewhat smaller device such as a wrist-watch device, pendant device, headphone device, earpiece device, or other wearable or miniature device, a cellular telephone, a media player, larger devices such as desktop computers, computers integrated into computer monitors, or other electronic devices.

Device 12 may include a connector such as connector 14. Connector 14 may have two contacts, three contacts, four contacts, five contacts, six contacts, six or more contacts, six or fewer contacts, seven contacts, seven or more contacts, seven or fewer contacts, thirty contacts, or any other suitable number of contacts.

Connector 14 may be coupled to different types of external equipment. As shown in FIG. 1, external equipment 16 of the type that may be connected to device 12 may include power supplies such as power adapter 18, accessories such as accessory 26, and testers such as tester 30 (as examples).

Power adapter 18 may convert alternating current power from alternating current (AC) source 20 into direct current (DC) signals at connector 22. When it is desired to charge a battery in device 12 or to otherwise provide power to device 12, power adapter connector 22 may be connected to mating electronic device connector 14, as illustrated by path 36.

Accessory 26 may include a connector such as connector 24 that mates with connector 14. Accessory 26 may be a mono or stereo headset with a microphone, a mono or stereo headset without a microphone, a charging station, an external set of speakers, a computer (e.g., a laptop or desktop computer that is being used to provide power to device 12 and/or that is being used to synchronize data with device 12), or other suitable accessories or external equipment. When it is desired to use accessory 26 with device 12, accessory connector 24 may be plugged into connector 14 of electronic device 12, as indicated by path 34.

Testing may be performed using tester 30. Tester 30 may be a Joint Test Action Group (JTAG) tester or test equipment that supports other testing protocols. JTAG testers sometimes use four or five pin interfaces (e.g., interfaces that include pins such as a JTAG test data input pin TDI, a JTAG test data output pin TDO, a JTAG clock pin TCK, a JTAG state machine control pin TMS, and, if desired, a reset pin). In some test environments, it may be desirable to minimize pin counts, so protocols such as the Serial Wire Debug (SWB) protocol have been developed that support testing over two pins (e.g., using a SWDIO data pin and a clock pin SWCLK). Serial Wire Debug interfaces can be used to support JTAG testing. Illustrative configurations in which tester 30 is a tester of the type that may support JTAG and/or Serial Wire Debug testing are sometimes described herein as an example. In general, however, tester 30 may support any suitable test protocols. As shown by path 32, test connector 28 of tester 30 may be mated with connector 14 of electronic device 12 when it is desired to test device 12.

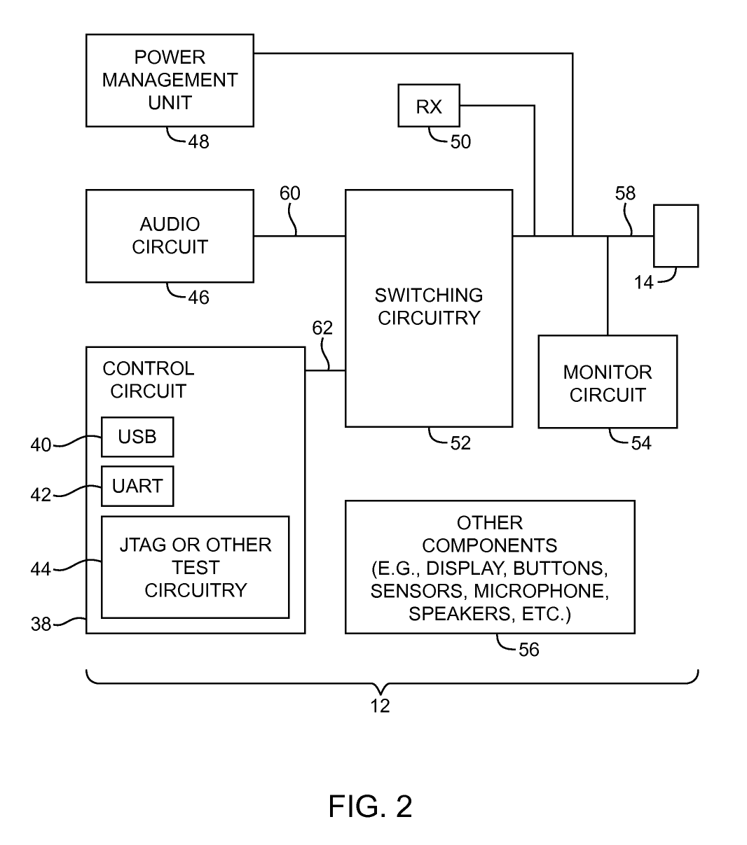

Illustrative circuitry that may be provided in electronic device 12 is shown in FIG. 2. As shown in FIG. 2, a path such as path 58 may be coupled to connector 14. Path 58 may include conductive traces on a printed circuit board or other substrate. Components such as integrated circuits, switches, sensors, and other devices may be mounted on the substrate. The traces or other conductive lines in path 58 may each be connected to a respective contact in connector 14. If, for example, connector 14 contains four contacts, each of the four contacts may be connected to a respective line in path 58.

Device 12 may use a monitor circuit such as monitor circuit 54 to monitor the status of connector 14. For example, monitor circuit 54 may monitor the contacts of connector 14 for the presence of a signal or connector characteristic that indicates that device 12 should enter a testing mode (e.g., a JTAG mode).

Switching circuitry 52 may be used to selectively couple the lines in communications path 58 to lines such as lines in paths 60 and 62. For example, during normal operation of device 12 by a user, switching circuitry 52 may be configured to route signals from connector 14 to audio circuit 46 using two or more lines in path 60. During test mode operations, switching circuitry 52 may be configured to route signals from connector 14 to test module 44 of control circuitry 38 via two or more lines in path 62.

Audio circuit 46 may be, for example, an audio integrated circuit that handles analog and/or digital audio signals. Functions such as media playback, microphone signal amplification, noise cancellation, digital-to-analog and analog-to-digital conversion, equalization, volume control, pin assignment swapping (e.g., to accommodate headsets in which the microphone and ground terminals are reversed), and other control and audio processing features may be handled by audio circuit 46. In some contexts, audio circuit 46 may be referred to as a codec. Non-audio functions may, if desired, be integrated into audio circuit 46 or provided using other circuits in device 12.

Control circuit 38 may be implemented using one or more integrated circuits. Control circuit 38 may, for example, be implemented using an integrated circuit of the type that is sometimes referred to as a system-on-a-chip (SOC) integrated circuit. System-on-a-chip integrated circuits generally include a processor and other circuits. Control circuit 38 may include memory or may be coupled to external storage (e.g., memory in components 56).

Control circuit 38 may include processing circuits such as one or more testing and communications modules. As an example, control circuit 38 may include a communications module such as Universal Serial Bus (USB) module 40, a communications module such as Universal Asynchronous Receiver Transmitter (UART) module 42, and other communications circuits. Control circuit 38 may include circuitry that is configured to support test mode operations such as testing circuitry 44. Testing circuitry 44 may support test protocols such as four or five wire JTAG protocols and/or protocols in which JTAG data is conveyed use a two-wire test interface such as a Serial Wire Debug interface.

Power management unit 48 may be used to handle operations associated with receiving external power through connector 14. For example, when power adapter 18 (FIG. 1) is coupled to connector 14, power management unit 48 may be used in routing the power from power adapter 18 to a battery within device 12 when the battery is in need of charging. Power management unit 48 may also route power to internal circuitry within device 12 when it is desired to power device 12 directly from externally supplied DC signals.

Accessories 26 (FIG. 1) such as headsets may include antennas. For example, wiring within a headset may serve as a frequency modulation (FM) antenna for device 12. Receiver circuitry 50 within device 12 can receive FM signals from the antenna via connector 14 and path 58.

Device 12 may contain other components 56. Components 56 may include one or more displays, status indicator lights, buttons, sensors, microphones, speakers, a battery, amplifiers, radio-frequency transceiver circuits, microprocessors, microcontrollers, volatile memory (e.g., dynamic random-access memory, static random-access memory, etc.), non-volatile memory (e.g., flash memory or other solid state storage), hard drives, application-specific integrated circuits, and other electrical components. These components may be interconnected with the other components shown in FIG. 2. For example, one or more rigid printed circuit boards (e.g., fiberglass-filled epoxy printed circuit boards) and/or flexible printed circuits (e.g., flex circuits formed from patterned conductive traces on flexible sheets of polyimide or other polymers) may serve as substrates onto which the components of FIG. 2 may be mounted. The storage and processing circuitry in device 12 such as the non-volatile and volatile memory in device 12, control circuit 38, microprocessor circuitry, and processing circuitry in application-specific integrated circuits in device 12 form control circuitry that can be used in running software for device 12, controlling the operation of switching circuitry 52 and other components 56 in device 12, etc.

To ensure that device 12 enters a JTAG test mode or other desired testing mode, device 12 may be provided with external input. The external input may take the form of insertion of a predefined connector into connector 14, signals that are supplied to connector 14 by tester 30, and/or other suitable input for directing device 12 to enter a test mode of operation.

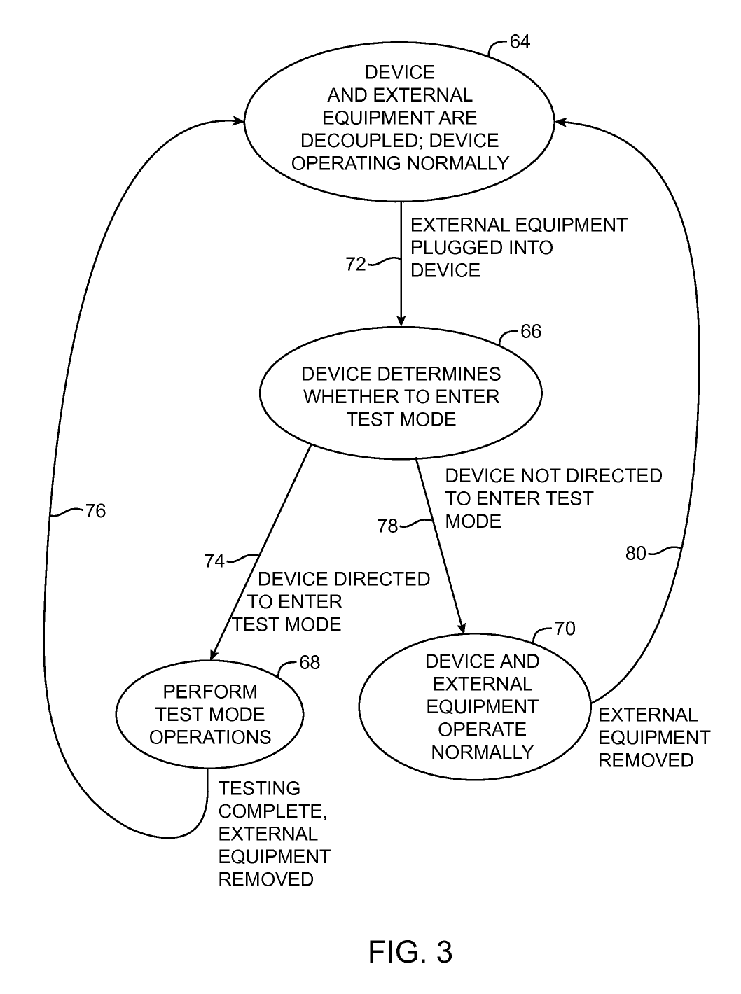

A state diagram showing operations involved in using device 12 in a system environment such as system 10 of FIG. 1 is shown in FIG. 3. During the operations of state 64, device 12 is disconnected from external equipment 16. In particular, device 12 is not connected to any accessories 26, device 12 is not connected to power adapter 18, and device 12 is not connected to tester 30.

As indicated by line 72, when a piece of external equipment 16 is plugged into device 10, device 12 may perform operations to determine whether to enter test mode (state 66). These operations may include, for example, using monitor circuit 54 to measure signals on the contacts of connector 14. Signal measurements may be made, for example, to compare the signals on the contacts to reference signals (e.g., to compare signal voltages to reference voltages), to compare the magnitudes of the signals to each other (e.g., to compare signal voltages on one or more contacts to signal voltages on one or more other contacts), to compute resistances, to evaluate the states of sensors that monitor whether a connector is plugged into connector 14, etc.

In response to a determination by device 12 that device 12 is not being instructed to enter test mode (i.e., because the external equipment that was connected to device 12 was a power adapter or other accessory and not a tester), device 12 may transition to state 70, as indicated by line 78. During the operations of state 70, device 12 and the external equipment that is connected to device 12 (e.g., power adapter 18 or other accessories such as accessory 26) may be operated normally. Once the external equipment is removed, device 12 may transition back to state 64, as indicated by line 80.

In response to a determination by device 12 that device 12 is being instructed to enter test mode (i.e., because the external equipment that was coupled to device 12 was a tester such as tester 30), device 12 may transition to state 68 (test mode), as indicated by line 74. During state 68, test circuitry 44 or other circuitry in control circuitry 38 that is configured to support test mode operations may be activated and used for handling test operations. For example, JTAG circuitry may be used to perform boundary scan test operations, may be used in conveying test data to tester 30, and may be used in performing other test operations for testing whether device 12 is operating satisfactorily. If errors are identified, a test operator may be alerted (e.g., by displaying an alert message on tester 30). Debugging operations may be performed in which test data captured by circuitry 44 is transmitted to tester 30 for analysis. Tester 30 may also direct the components of device 12 to perform various actions (e.g., adjusting integrated circuit settings, etc.) and may evaluate the ability of device 12 to execute these actions.

Once testing has been completed, tester 30 may be disconnected from connector 14 and, as indicated by line 76, device 12 may be operated while being decoupled from external equipment (state 64).

Switching circuitry 52 may contain electronic switches that are controlled by control signals from control circuitry in device 12 (e.g., control circuit 38 and/or other storage and processing circuitry in device 12). Switches within switching circuitry 52 may be based on transmission gates (e.g., gates based on metal-oxide-semiconductor transistors) or other electrically controllable switch technologies.

There may be any suitable number of switches in switching circuitry 52 (e.g., one or more, two or more, five or more, ten or more, etc.). The number of switches that are used in switching circuitry 52 may be selected to provide a desired amount routing flexibility for signals within device 12. For example, if it is desired to be able to route a set of audio signals from connector 14 to audio circuit 46 in either normal or reversed configuration (e.g., to accommodate normal and reversed microphone/ground line pin assignments in connector 14), switching circuitry 52 may be provided with sufficient switching resources to route the microphone and ground contacts in connector 14 to a pair of respective pins in audio circuit 46 in a normal configuration or in a configuration in which the signals are reversed).

As another example, if it is desired to route signals from a contact in connector 14 to several possible destinations such as a pin in audio circuit 46, a pin associated with USB module 40, a pin associated with UART module 42, and a pin associated with test circuitry 44, switching circuitry 52 may be provided with switches for forming a multiplexing circuit that is capable of selecting which of these various paths should be formed in device 12. Configurations for switching circuitry 52 that include relatively more switches may be used to provide enhanced amounts of interconnection flexibility, whereas configurations for switching circuitry 52 that include relatively fewer switches may be used to conserve device resources.

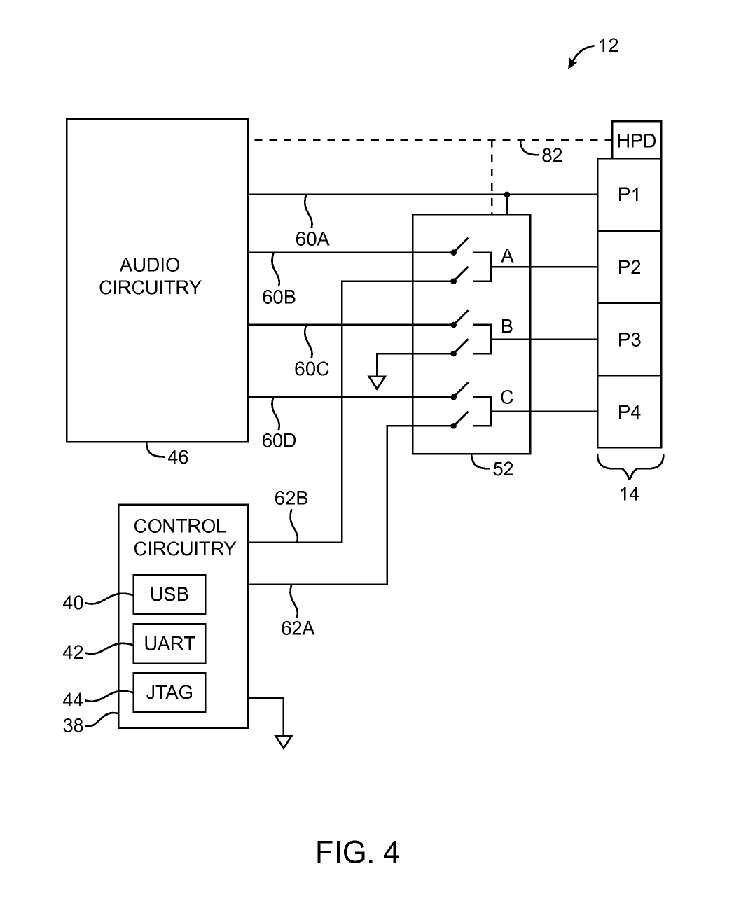

FIG. 4 is a circuit diagram showing an illustrative configuration that may be used for electronic device 12 in which switching circuitry 52 includes at least three sets of switches. Connector 14 in the example of FIG. 4 has four contacts (pins P1, P2, P3, and P4). Signals from contact P2 may be routed to audio circuitry 46 via path 60B or control circuitry 38 via path 62B using switching circuitry A. Signals from contact P3 may be routed to audio circuitry 46 via path 60C or to control circuitry 38 via path 62A using switching circuitry B. Switching circuitry C may be used to route signals from contact P4 to audio circuitry 46 via path 60D or to control circuitry 38 via path 62A. Using a switching scheme of the type shown in FIG. 4, signals may, if desired, be routed to audio circuitry 46 and control circuitry 38 simultaneously from a given contact in connector 14. If desired, switching circuitry 52 may contain switches that only allow signals to be routed to audio circuitry 46 or control circuitry 38, but not both simultaneously. The arrangement of FIG. 4 is merely illustrative.

Switching circuitry 52 and audio circuitry 46 or other circuitry in device 12 may, if desired, receive a signal from connector 14 via path 82. This signal may be used in connection with the signal on path 60A to determine whether a mating connector has been inserted into connector 14 in the position associated with contact P1. Consider, as an example, a configuration in which contact 14 is a four pin female audio connector (sometimes referred to as an audio jack or four-contact audio connector). This type of connector, which is also sometimes referred to as a TRRS (tip-ring-ring-sleeve) connector, may use contact P1 to mate with a corresponding tip contact in a four-pin male audio connector (sometimes referred to as an audio plug), may use contact P2 to mate with a first corresponding ring contact in a four-pin male audio connector, may use contact P3 to mate with a second corresponding ring contact in a four-pin male audio connector, and may use contact P4 to mate with a sleeve contact in a four-pin male audio connector.

With one suitable configuration, which is sometimes described herein as an example, contact P1 of connector 14 may be associated with a left channel of audio L. Contact P2 of connector 14 may be associated with a right channel of audio R during normal operation. During testing (e.g., JTAG testing), contact P2 may be associated with a signal SWDIO (e.g., a first of two Serial Wire Debug signals). During normal operation, contact P3 may be associated with ground and contact P4 may be associated with a microphone signal from a microphone in an attached accessory (e.g., a headset with a microphone or other accessory 26). In some geographic regions, convention may dictate that the normal pin assignments for contacts P3 and P4 be reversed (i.e., so that contact P3 is used for microphone signals and so that contact P4 serves as a ground terminal). During testing, contact P4 may be associated with a signal SWCLK (e.g., a second of two Serial Wire Debug signals). The signals SWDIO and SWCLK may, if desired, form a testing interface that is used for handling JTAG test data.

To detect whether the tip of an audio plug has been received properly within the tip portion of the audio jack (connector 14), connector 14 may be provided with a sensor that detects the presence (absence) of the audio plug tip portion in the vicinity of contact P1. A mechanical sensor, optical sensor, electrical sensor, or any other suitable type of sensor may be used to detect the presence of all or part of an audio plug within connector 14.

As one example, a sensor (sometimes referred to as a headphone detect sensor) may be implemented by measuring the resistance between a pair of contacts associated with pin P1. The first contact may be, for example, pin P1 itself and the second contact (illustrated as contact HPD in FIG. 4) may be an ancillary contact that is configured to form an electrical connection with a properly positioned tip connector on an inserted audio plug. Control circuitry in device 12 (e.g., headphone detection circuitry in switching circuitry 52, audio circuitry 46, control circuitry 38, or other control circuitry in device 12) may be used in evaluating the resistance between contacts HPD and P1 in real time.

When the measured resistance between sensor contacts HPD and P1 is relatively high (e.g., over a predefined threshold level), it can be assumed that the tip contact portion of the male audio connector is not present. When the measured resistance between HPD and P21 is low (e.g., below the predefined threshold level), device 12 can conclude that the tip contact from the audio plug has been inserted into connector 14 (e.g., the audio plug is present). Different actions can be taken depending on whether or not the audio tip is present (e.g., actions related to configuring switching circuitry 52 and/or using audio circuitry 46 and/or circuitry such as control circuitry 38).

In the example of FIG. 4, path 82 and path 60A are coupled to circuitry 46 and circuitry 52, illustrating how circuitry 46 and/or circuitry 52 may be used in monitoring the resistance between contacts HPD and P1 to determine whether or not the tip of an audio plug has been received within connector 14. If desired, control circuitry 38 or other control circuitry in device 12 may be used to measure the resistance between HPD and P1 to detect the presence of the audio plug tip.

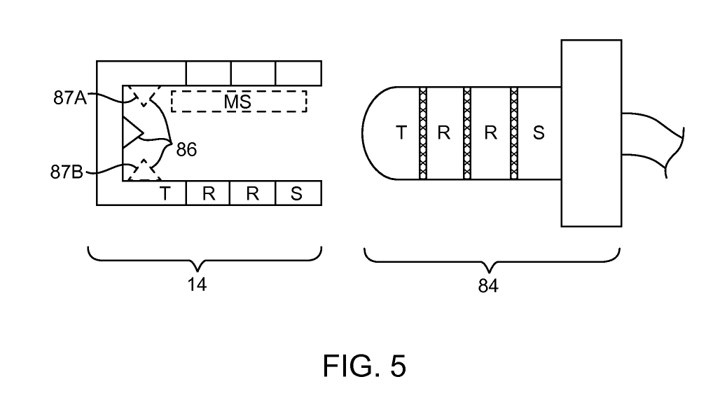

FIG. 5 is a cross-sectional side view of a connector such as connector 14 of device 12 in a configuration in which connector 14 has been implemented using an audio connector with four contacts (T, R, R, and S). If desired, connector 14 may be a three-pin audio connector (e.g., a TRS connector). The example of FIG. 5 in which connector 14 is a four-pin (TRRS) audio connector is merely illustrative.

Connector 14 may be an audio jack (female audio connector) that mates with corresponding audio plugs (male audio connectors) such as audio plug 84 that has corresponding tip (T), ring (R), ring (R), and sleeve (S) contacts. Audio plug 84 may be associated with any suitable type of external equipment 16. For example, audio plug 84 may serve as connector 22 of power adapter 18, connector 24 of accessory 26, or connector 28 of tester 30 (FIG. 1). Audio plug 84 may have a cylindrical body (e.g., a cylindrical elongated portion with a diameter of ⅛″ or other suitable diameter).

Optional contact 86 may serve as contact HPD of FIG. 4. Control circuitry in device 12 can monitor the resistance between terminals T and 86 to determine when an audio plug is inserted into connector 14. Other sensors (e.g., sensors associated with terminals R, R, and S, mechanical sensors such as sensor MS that can detect whether connector 84 has been inserted into connector 14 or other sensors) may be used in monitoring the status of connector 84 and connector 14.

As shown in FIG. 5, connector 14 may include one or more contacts 86. Contacts 86 may be provided at one or more locations within connector 14. As examples, contact 86 may be located along the center axis of connector 14 (as shown by the solid version of contact 86) and one or more contacts 86 may be located across from tip contact T of connector 84 when connector 84 is inserted into connector 14 (as shown by dashed version 87A and 87B of contact 86). Arrangements in which contact 86 is located in positions such as positions 87A an 87B may facilitate detection of split plugs 84 (e.g., plugs formed from half of a cylinder).

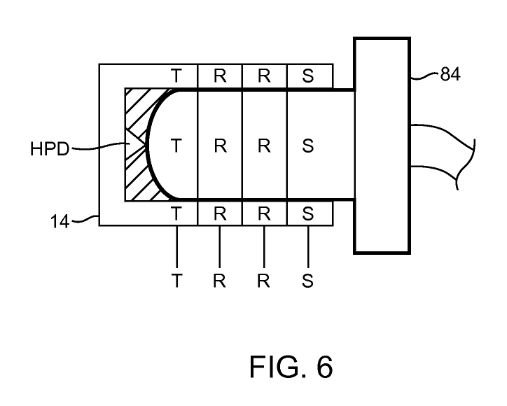

FIG. 6 is a cross-sectional side view of an illustrative configuration in which connector 14 for device 12 has been provided with a contact (contact HPD) for use in detecting the presence of tip contact T in audio plug 84. Control circuitry in device 12 may monitor the resistance between contact HPD and contact T in connector 14. When audio connector 84 is inserted into connector 14, the measured resistance between HPD and tip T in connector 14 will be low (i.e., HPD and contact T in connector 14 will be shorted together, indicating the presence of plug 84).

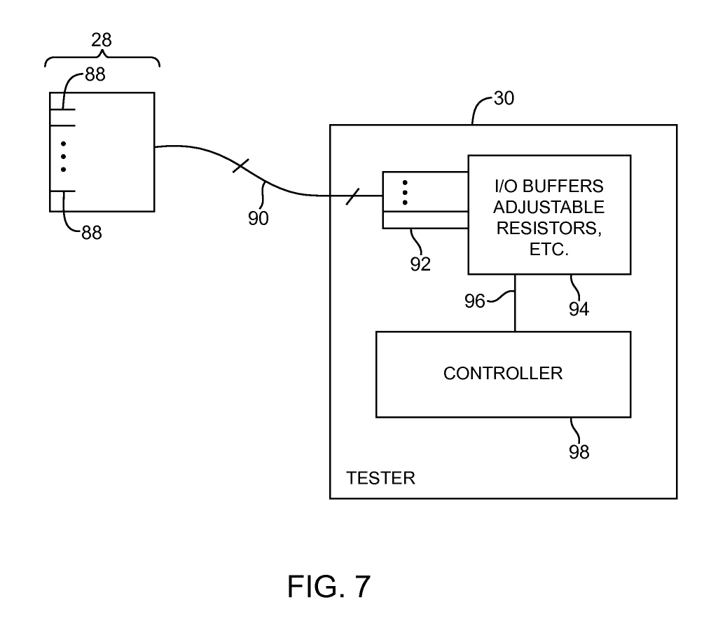

FIG. 7 is a circuit diagram showing an illustrative configuration that may be used for tester 30 of FIG. 1. As shown in FIG. 7, tester 30 may include control circuitry such as controller 98. Controller 98 may be based on one or more microprocessors, one or more microcontrollers, one or more application-specific integrated circuits, or other control circuitry.

Controller 98 may be coupled to control circuitry such as input-output circuitry 94 via paths such as path 96. Input-output circuitry 94 may include input-output buffers (e.g., output drivers capable of generating voltages at adjustable and/or fixed voltages of desired magnitudes), adjustable resistors, adjustable current sources, or other input-output circuitry. Conductive paths 92 (e.g., traces on a printed circuit board or other substrates) may be used to couple output signals from output buffers, adjustable resistors, and other input-output circuitry 94 to respective lines in path 90. Each of lines 92 may be coupled between a respective input-output pin associated with circuitry 94 and a conductive path such as a conductive wire in path 90. Path 90 may be implemented using a cable containing wires that are connected to respective contacts 88 in a pigtailed connector (connector 28), as shown in FIG. 7. There may be any suitable number of contacts 88 in connector 28. For example, connector 28 may be three-contact audio plug (e.g., a ⅛″ TRS plug) or a four-contact audio plug (e.g., a ⅛″ TRRS plug).

During testing, control circuitry in tester 30 such as controller 98 and input-output circuitry 94 may provide commands to a device under test that direct the device under test to enter test mode. For example, tester 30 may use controller 98 and input-output circuitry 94 to produce a particular pattern of voltages (or resistances) at contacts 88. These signals may be detected by monitoring circuitry in the device under test.

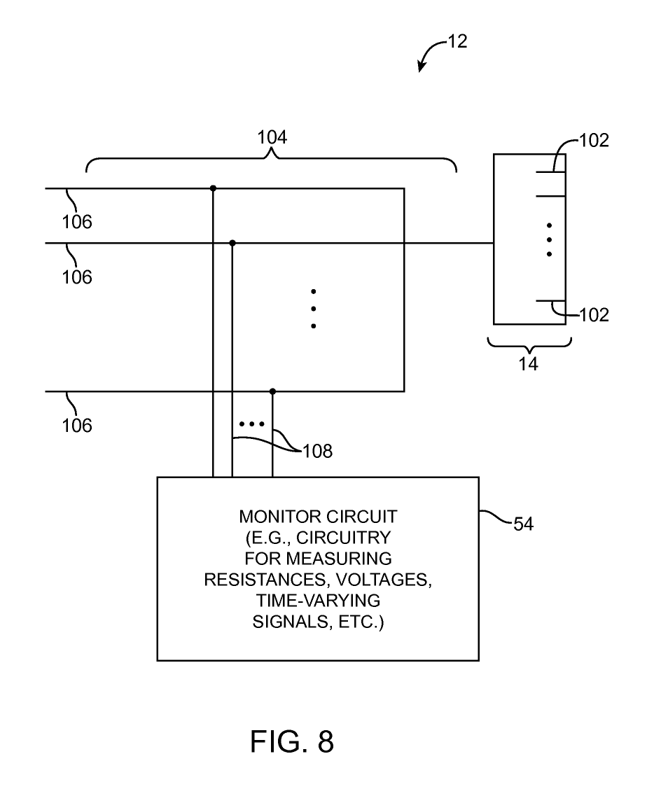

FIG. 8 shows how monitoring circuitry 54 of device 12 may be coupled to communications path 104. Communications path 104 may have conductive lines that are coupled to respective contacts 102 in connector 14. For example, in a configuration in which connector 28 of FIG. 7 is a four-contact audio plug, connector 14 of FIG. 8 may be a mating four-contact audio jack. In this type of arrangement, path 104 may include four conductive lines, each of which is connected to a respective one of contacts 102. Lines 106 in path 104 may be coupled to internal circuitry in device 12 (e.g., switching circuitry 52, receiver 50, power management unit 48, etc.). Lines 108 in path 104 may be used to connect contacts 102 in connector 14 to monitor circuit 54.

Monitor circuit 54 may measure voltages, currents, resistances, time-varying signals, or other suitable input associated with connector 14. For example, monitor circuit 54 may detect when tester 30 (FIG. 7) has used input-output circuit 94 to place a predetermined voltage or pattern of voltages on one or more of contacts 102. In response to detection of different voltages on contacts 102, device 12 can be placed in different respective states.

As an example, when tester 30 desires to place device 12 in test mode, tester 30 can place a predetermined voltage on one of contacts 102 such as a microphone (M) contact. In response to detection of the predetermined voltage on the microphone contact with monitor circuitry 54, device 12 can be placed in test mode (e.g., using JTAG or other test circuitry 44 to perform tests and communicate with tester 30).

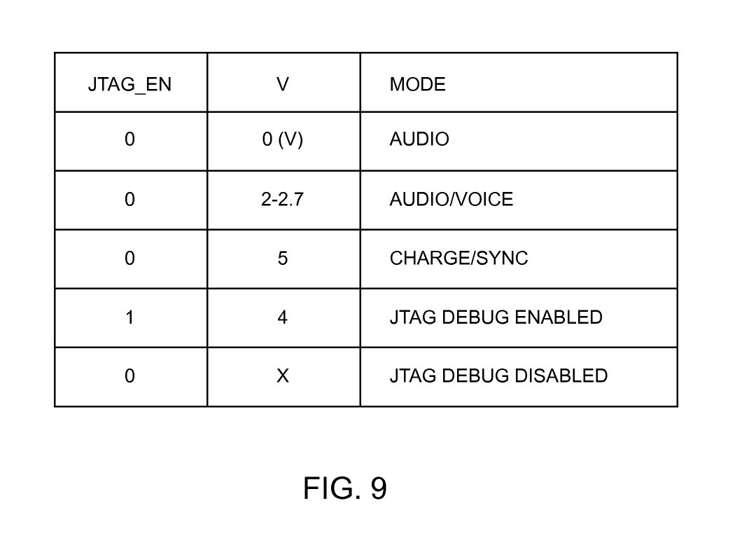

FIG. 9 is a table of illustrative voltages that may be used on a microphone contact or other contact 102 in connector 14 in various modes of operation for device 12. As shown in the table of FIG. 9, a voltage of 0 volts may be placed on the microphone contact during normal audio playback operations (e.g., when playing back left and right audio from device 12 to an attached accessory using audio circuit 46). When it is desired to capture voice signals or other audio signals using a microphone in an attached accessory, device 12 may place a microphone bias voltage of 2-2.7 volts on the microphone terminal in connector 14. Accessory 24 (e.g., an attached headset with a microphone) may use the 2-2.7 volt signal on the microphone terminal to bias the microphone. At the same time that the microphone is being biased, microphone signals (e.g., voice signals at audio frequencies) from the microphone can be processed using audio circuit 46. During audio mode operations (the first row of the table of FIG. 9) and audio/voice mode operations (the second row of the table of FIG. 9), switching circuitry 52 can be configured to couple audio circuit 46 and path 60 to path 58 and connector 14.

As shown in the third row of the table of FIG. 9, a voltage of 5 volts may be placed on the microphone contact during charging and syncing operations (e.g., when device 12 is being charged from an external device and/or when device 12 and external equipment are communicating using a protocol such as a Universal Serial Bus protocol). Communications using the Universal Serial Bus protocol may be supported using circuitry 40 of FIG. 2. Switching circuitry 52 can be configured to couple control circuitry 38 (FIG. 1) and path 62 to path 58 and connector 14 during sync operations.

When tester 30 desires to force device 12 into test mode, controller 98 in tester 30 may use an adjustable or fixed output buffer in input-output circuitry 94 to place a 4 volt signal (e.g., a signal in a voltage range of about 3.6 to 4.4 volts or other suitable voltage range) on the microphone terminal of connectors 28 and 14. Monitor circuit 54 may measure the voltage on the microphone line (e.g., using a voltage detector or other suitable circuitry). When a voltage with the predetermined magnitude of about 4 volts is detected, device 12 (e.g., control circuitry in device 12) can activate JTAG or other test circuitry 44 for use in supporting test mode operations (i.e., device 12 may be forced into test mode). Switching circuitry 52 may also be configured to ensure that path 62 is coupled to path 58 (e.g., so that JTAG circuitry 44 is coupled to appropriate contacts in connector 14). Other predetermined voltages may be supplied to the microphone terminal if desired. For example, tester 30 may supply a voltage of 3 volts to force device 12 into a UART mode using UART circuitry 42 of FIG. 2 to communicate over path 62, switching circuitry 52, and path 58. In general, circuitry in device 12 and/or circuitry in tester 30 may be used in placing voltages on the connector contacts.

If desired, JTAG circuitry 44 may be enabled and disabled using a control signal such as a JTAG enable signal (JTAG_EN). For example, JTAG circuitry 44 may be maintained in a disabled state prior to authentication between device 12 and tester 30 (e.g., using a protocol such as a Secure JTAG protocol). By requiring authentication, JTAG attacks may be thwarted (e.g., tester 30 may be assured of the authenticity of device 12, device 12 can be assured that data received from tester 30 is authorized, and communications between tester and 30 and device 12 can be secured against unauthorized interception). Prior to authentication, JTAG_EN may be deasserted (e.g., held low at a logic “0” value as shown in FIG. 9). Following successful authentication, JTAG_EN may be asserted (e.g., held high at a logic “1” value as shown in FIG. 9).

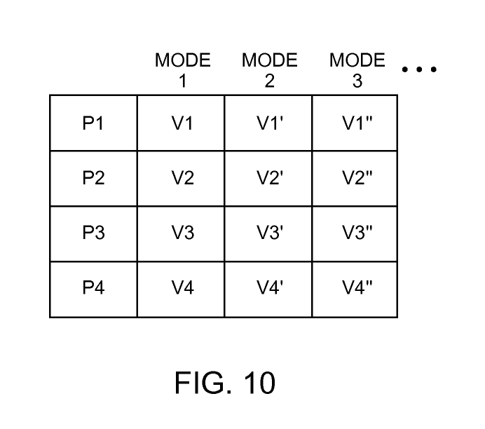

In the example of FIG. 9, the magnitude of the direct current (DC) voltage on a single connector contact (i.e., the microphone contact) was used in controlling the mode of operation for device 12. If desired, patterns of voltages on multiple contacts associated with connector 14 (and connector 28) may be used in controlling the operating mode of device 12. FIG. 10 is a table illustrating how patterns of voltages may be associated with different operating modes. In the example of FIG. 10, connector 14 is a four-contact connector such as a four-pin audio connector. Connector 14 (in this example), may have four contacts P1, P2, P3, and P4. Monitor circuit 54 may measure the voltage on each of contacts P1, P2, P3, and P4, using paths 108 (FIG. 8).

When the pattern of voltages shown in the “mode 1” column of the table of FIG. 10 is provided to connector 14 (i.e., when voltage V1 is provided to contact P1, V2 is provided to contact P2, V3 is provided to contact P3, and V4 is provided to contact P4 by tester 30), device 12 may be placed in a first mode of operation (e.g., “mode 1”). When the pattern of voltages V1′, V2′, V3′, and V4′ associated with the “mode 2” column of the FIG. 10 table is provided to connector 14, device 12 may be placed in a second mode of operation (e.g., “mode 2”). When the pattern of voltages V1″, V2″, V3″, and V4″ associated with the “mode 3” column of the FIG. 10 table is provided to connector 14, device 12 may be placed in a third mode of operation (e.g., “mode 3”), etc. Voltages V1, V2, V3, V4, V1′, V2′, V3′, V4′, V1″, V2″, V3″, and V4″ may have any suitable values ranging from 0 volts to 5 volts (as an example).

If desired, fewer than four voltages may be supplied to contacts 102. For example, voltages V1 and V2 may be provided to contacts P1 and P2, respectively, while contacts P3 and P4 are left floating (as an example). The configurations of FIG. 10 in which patterns of four voltages on four respective contacts in connector 14 are used to direct device 12 to enter different modes of operation is merely illustrative. The modes of operation into which device 12 is placed (e.g., modes 1, 2, and 3 in the FIG. 10 example) may correspond to different configurations for the control circuitry of device 12. For example, mode 1 may correspond to a normal mode of operation in which audio circuit 46 and path 60 are coupled to path 58 and connector 14 using switching circuitry 52. Mode 2 may correspond to a JTAG test mode or other test mode in which JTAG or other test circuitry 44 is active and in which switching circuitry 52 is configured to use path 62 to couple circuitry 44 to path 58 and connector 14. Mode 3 may correspond to a mode in which UART circuitry 42 is coupled to connector 14 by switching circuitry 52 and a fourth mode (“mode 4”) may correspond to a mode in which USB circuitry 40 is coupled to connector 14 by switching circuitry 52. The reconfiguration of circuitry 52 in response to receiving different patterns of voltages (e.g., DC voltages) on the pins of connector 14 allows device 12 to be placed into appropriate operating modes during testing with tester 30.

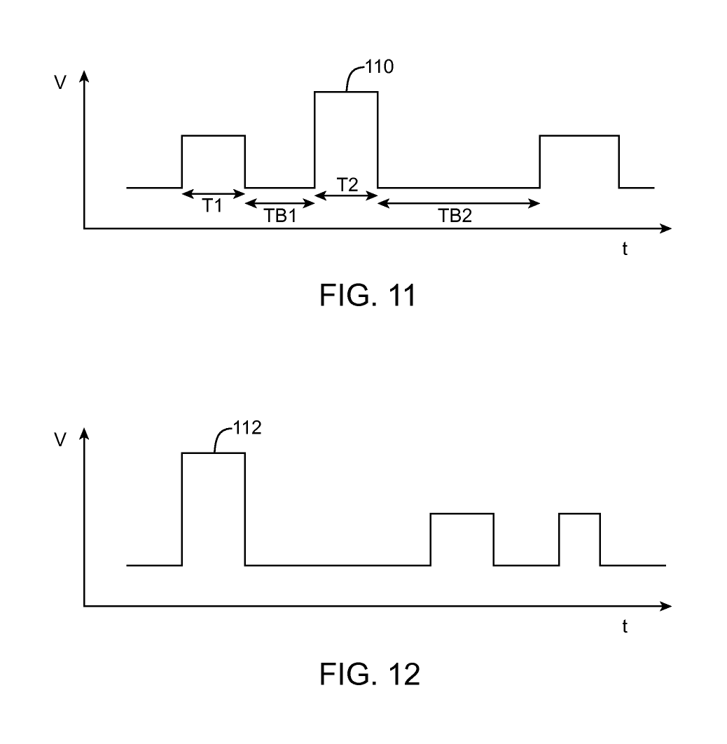

If desired, tester 30 may use controller 98 and input-output circuitry 94 or other control circuitry to generate time-varying signals on contacts 88 of connector 28. Monitor circuit 54 (FIG. 8) of device 12 may detect these time-varying signals on mating contacts 102 of connector 14 and may direct device 12 to respond accordingly. Curve 110 in the graph of FIG. 11 shows an illustrative time-varying control signal that tester 28 may supply to one of the contacts of connector 14 to place device 12 in a test mode or other desired mode of operation. As shown in FIG. 11, curve 110 may have pulses with different maximum voltages. The pulse may have differing pulse widths (e.g., time periods T1 and T2 for the illustrative first and second pulses in FIG. 11). The pulses may also be separated by varying amounts of time (e.g., the first and second pulses may be separated by time period TB1, the second and third pulses in the signal of curve 110 may be separated by time period TB2, etc.). The attributes of the signal produced by tester 30 may be used in directing device 12 to enter a desired mode of operation. For example, attributes such as signal magnitude, pulse width, pulse spacing, and other attributes of signal 110 may be combined to serve as a code that allows tester 30 to inform device 12 of a desired operating mode. If desired, pulses in a coded signal may have identical magnitudes and/or identical widths and/or non-square shapes). The example of FIG. 11 is merely illustrative.

Curve 112 of FIG. 12 shows how a different pattern of pulses with different magnitude and/or timing attributes may be supplied to device 12 by tester 30 when it is desired to place device 12 in a different mode of operation. Time varying signals such as the illustrative signals of FIGS. 11 and 12 may be applied to a single contact in connector 14 (e.g., the microphone contact or other contact) or multiple time-varying and/or fixed signals can be applied to multiple contacts 102. As an example, a single such as signal 110 of FIG. 11 may be applied to a first one of contacts 102 while a signal such as signal 112 of FIG. 12 is being applied to a second one of contacts 102. By using different combinations of signals, tester 30 can produce additional codes that are used to place device 12 in different respective modes of operation (as an example).

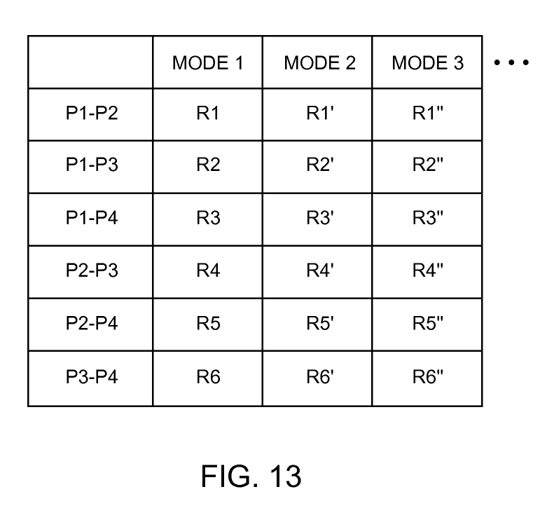

If desired, tester 30 may use controller 98 and input-output circuitry 94 to impose patterns of one or more different resistances across different respective pairs of contacts 102 to place device 12 into desired modes of operation. As shown in FIG. 13, for example, tester 30 may place a resistance R1 across terminals P1 and P2, a resistance R2 across terminals P1 and P3, a resistance R3 across terminals P1 and P4, a resistance R4 across terminals P2 and P3, a resistance R5 across terminals P2 and P4, and a resistance R6 across terminals P3 and P4. In response, monitor circuit 54 may detect this pattern of resistances (or any suitable subset of these resistances) and the control circuitry of device 12 may be directed to enter a desired mode of operation. As shown in the columns of the table of FIG. 13, the adjustable resistors or other circuitry of input-output circuitry 94 (FIG. 7) may be used in creating different patterns of resistances across the contacts in connector 28 (and therefore different corresponding patterns of resistances across the contacts in connector 14) to place device 12 in different modes of operation (e.g., mode 2, mode 3, etc.).

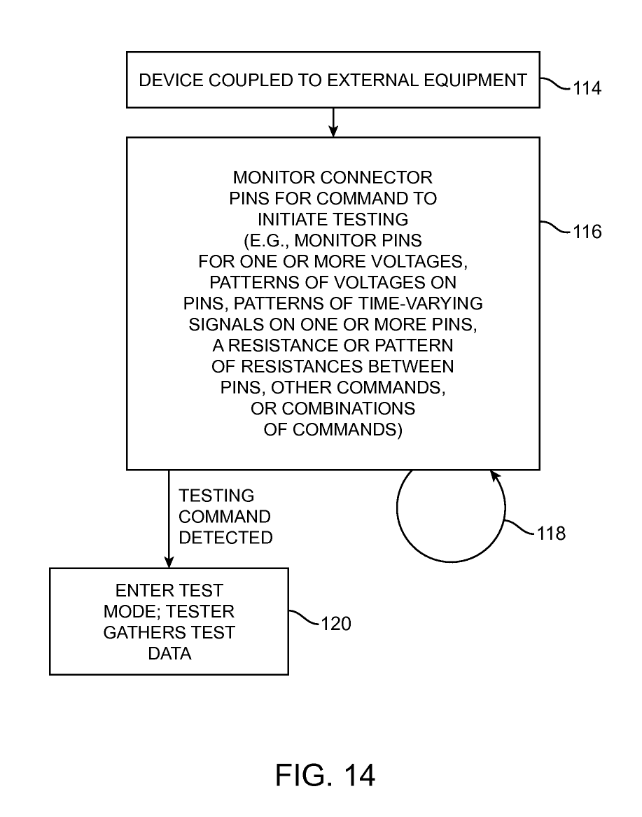

FIG. 14 is a flow chart of illustrative steps involved in operating devices such as device 12 of system 10 (FIG. 1). Initially, device 12 may be disconnected from any external equipment 16. At step 114, device 12 may be coupled to external equipment 16. For example, connector 22 of power adapter 18, connector 24 of accessory 26, or connector 28 of tester 30 may be connected to connector 14 of device 12.

At step 116, device 12 may use monitor circuit 54 to monitor signals on contacts 102. Monitor circuit 54 may, for example, monitor one or more of contacts 102 to detect voltage levels, resistances, time-varying signals, patterns of signals on multiple contacts, signals with particular values on a single one of contacts 102, etc.

If the signals that monitor circuit 54 detects on contacts 102 of connector 14 indicate that device 12 should be operated normally (e.g., in a non-test mode), device 12 may be operated normally while monitor circuit 54 continues to monitor the status of contacts 102 (e.g., to detect voltages, to detect resistances, to detect time-varying signals, etc.), as indicated by line 118. During these operations, switching circuitry 52 may, as an example, have a normal configuration such as a configuration that couples audio circuit 46 (FIG. 2) to connector 14.

In response to detection of a particular signal or pattern of signals (e.g., a predetermined voltage on one contact, a predetermined pattern of voltages on multiple contacts, a resistance or resistances associated with one or more pairs of contacts, a predetermined time-varying signal, or other signals that serve as commands to device 12 to enter test mode), device 12 may enter test mode (step 120). During test mode operations, switching circuitry 52 may be configured to support test operations and testing circuitry may be activated. For example, path 62 may be coupled to path 58 using switching circuitry 52 and JTAG or other testing circuitry 44 may be used to perform test mode operations.

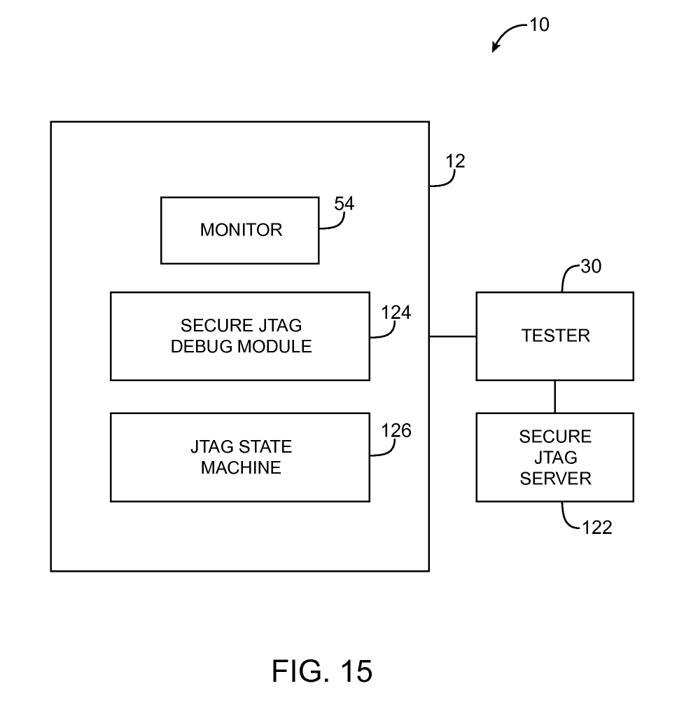

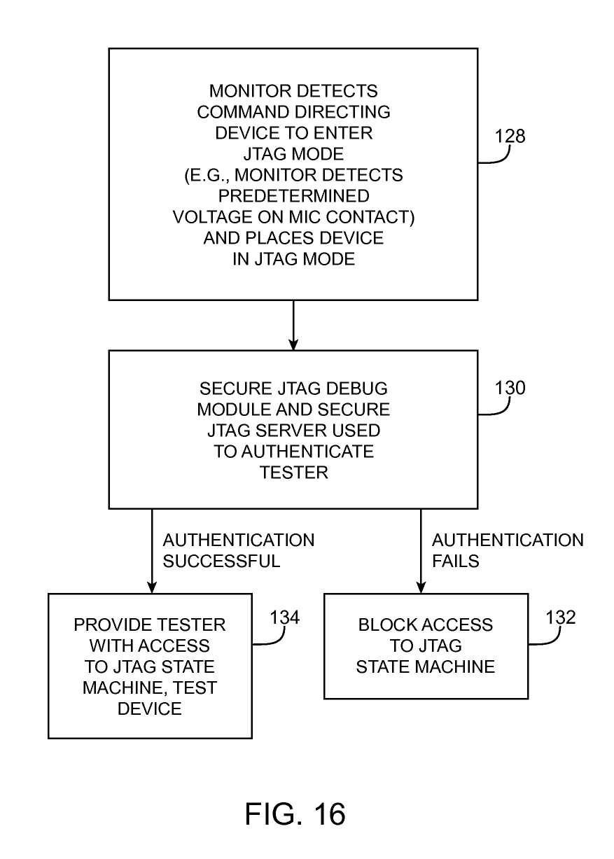

If desired, test mode operations may be secured using a protocol such as a Secure JTAG protocol. As shown in FIG. 15, system 10 may include a security server such as Secure JTAG server 122. Secure JTAG server 122 and device 12 may perform authentication operations to ensure that device 12 and/or tester 30 are authorized for test mode operations. The control circuitry of device 12 may be configured to implement Secure JTAG debug module 124 and JTAG state machine 126. As shown in FIG. 16, monitor circuit 54 of device 12 may detect an incoming command from tester 30 at step 128. Monitor circuit 54 may, for example, detect a predetermined voltage on a microphone contact or other contact in connector 14, may detect a predetermined pattern of voltages, may detect one or more predetermined resistance values associated with one or more pairs of the contacts in connector 14, may detect a predetermined time-varying signal pattern, may detect the occurrence of two or more of these inputs, or may detect other signals from tester 30 that direct device 12 to enter test mode.

In response to detection of signals from tester 30 to enter test mode, Secure JTAG debug module 124 and Secure JTAG server 122 may be used to authenticate tester 30 (step 130). If authentication fails, access to JTAG state machine 126 may be blocked (step 132). If authentication is successful, tester 30 may be provided with access to JTAG state machine 126 and device 12 may be tested by tester 30 (step 134). During testing, the control circuitry of device 12 may configure switching circuitry 52 to support test mode operations.

The foregoing is merely illustrative of the principles of this invention and various modifications can be made by those skilled in the art without departing from the scope and spirit of the invention.

What is claimed is:

1. An electronic device, comprising:
a first circuit;
a second circuit, wherein the second circuit comprises test circuitry configured to support test mode operations;
a device connector that is configured to couple to a tester;
switching circuitry coupled between the first and second circuits and the device connector, wherein the switching circuitry is configured to route signals from the device connector to the first circuit during normal operation and is configured to route signals from the device connector to the second circuit during the test mode operations; and
control circuitry configured to monitor at least one contact in the device connector for at least one signal from the tester, wherein the control circuitry is configured to adjust the switching circuitry in response to detection of the at least one signal from the tester.

2. The electronic device defined in claim 1 wherein the first circuit comprises an audio circuit.

3. The electronic device defined in claim 2 wherein the second circuit comprises circuitry configured to perform Joint Test Action Group test operations.

4. The electronic device defined in claim 1 wherein the at least one signal from the tester comprises a predetermined voltage and wherein the control circuitry is configured to adjust the switching circuitry in response to detection of the predetermined voltage.

5. The electronic device defined in claim 4 wherein the device connector comprises an audio jack, wherein the at least one contact forms part of the audio jack, and wherein the control circuitry is configured to adjust the switching circuitry in response to detection of the predetermined voltage on the at least one contact in the audio jack.

6. The electronic device defined in claim 1 wherein the device connector comprises an audio jack, wherein the at least one contact comprises a microphone contact in the audio jack, wherein the at least one signal from the tester comprises a predetermined voltage that is applied to the microphone contact, and wherein the control circuitry is configured to adjust the switching circuitry in response to detection of the predetermined voltage on the microphone contact.

7. The electronic device defined in claim 6 wherein the first circuit comprises an audio circuit and wherein the second circuit comprises circuitry configured to perform Joint Test Action Group test operations.

8. The electronic device defined in claim 1 wherein the at least one signal from the tester comprises a time-varying voltage and wherein the control circuitry is configured to adjust the switching circuitry in response to detection of the time-varying voltage.

9. The electronic device defined in claim 8 wherein the time-varying voltage includes at least two signal pulses, wherein the first circuit comprises an audio circuit, and wherein the second circuit comprises circuitry configured to perform Joint Test Action Group test operations.

10. The electronic device defined in claim 1 wherein the device connector comprises an audio jack having at least three contacts and wherein the control circuitry is configured to adjust the switching circuitry in response to detection of a pattern of different voltages on the at least three contacts.

11. The electronic device defined in claim 10 wherein the pattern of voltages comprises a first voltage on a first of the at least three contacts, a second voltage that is different than the first voltage on a second of the at least three contacts, and a third voltage that is different than the first and second voltages on a third of the at least three contacts, wherein the first circuit comprises an audio circuit, and wherein the second circuit comprises circuitry configured to perform Joint Test Action Group test operations.

12. The electronic device defined in claim 1 wherein the device connector comprises an audio jack having at least two contacts and wherein the control circuitry is configured to adjust the switching circuitry in response to detection of a predetermined resistance value across the at least two contacts.

13. The electronic device defined in claim 12 wherein the first circuit comprises an audio circuit and wherein the second circuit comprises circuitry configured to perform Joint Test Action Group test operations.

14. A method, comprising:
coupling a tester to an electronic device that includes an audio circuit and a controller that are coupled to a connector through switching circuitry; and
applying at least one signal to the connector from the tester that directs the device to adjust the switching circuitry to route signals from the connector to the controller and that directs the controller to support test mode operations, wherein the at least one signal comprises at least one signal selected from the group consisting of: a predetermined voltage on a microphone contact in the connector, at least one predetermined resistance across at least a pair of contacts in the connector, a pattern of different voltages on respective contacts in the connector, and at least one time-varying voltage on at least one contact in the connector.

15. The method defined in claim 14 wherein the connector comprises an audio connector having at least three contacts including the microphone contact and wherein applying the at least one signal to the connector comprises applying the predetermined voltage to the microphone contact in the audio connector.

16. The method defined in claim 15 wherein the controller comprises circuitry configured to perform Joint Test Action Group test operations.

17. The method defined in claim 14 wherein the connector comprises an audio connector having at least three contacts and wherein applying the at least one signal comprises applying the predetermined resistance across at least a first and second of the three contacts.

18. The method defined in claim 14 wherein the connector comprises an audio connector having at least three contacts and wherein applying the at least one signal comprises applying the pattern of different voltages to the audio connector by supplying a different respective voltage to each of the three contacts in the audio connector.

19. The method defined in claim 14 further comprising:
using a secure Joint Test Action Group debug module to perform authentication operations in response to detection of the at least one signal;
in response to successful authentication when performing the authentication operations, using the controller to perform Joint Test Action Group test operations with a Joint Test Action Group state machine; and
in response to failed authentication when performing the authentication operations, using the controller to block access to the Joint Test Action Group state machine by the tester.

20. An electronic device, comprising:
an audio circuit;
a control circuit configured to support test mode operations when testing the electronic device;
a device connector that is configured to couple to a tester;
switching circuitry coupled between the audio circuit, the control circuit, and the device connector, wherein the switching circuitry is configured to route signals from the device connector to the audio circuit during normal operation and is configured to route signals from the device connector to the control circuit during the test mode operations; and
a monitor circuit that monitors signals on at least one contact in the device connector, wherein the switching circuitry is adjusted to route signals from the device connector to the control circuit in response to detection of a predetermined signal on the device connector.

21. The method defined in claim 20 wherein the device connector comprises an audio connector having left, right, microphone, and ground contacts and wherein the predetermined signal comprises a predetermined voltage received from the tester on the microphone contact.

22. The method defined in claim 21 wherein the controller comprises circuitry configured to perform Joint Test Action Group test operations in response to detection of the predetermined voltage on the microphone contact of the audio connector.
